(19) United States
(12) Patent Application Publication
(10) Pub. No.: US 2026/0139403 A1
(43) Pub. Date: May 21, 2026

(54) LEAD DECAHYDROXYDECABORATE DIHYDROXY MONOBORATE MONOHYDRATE NONLINEAR OPTICAL CRYSTAL, PREPARATION METHOD AND APPLICATION THEREOF

(71) Applicant: XINJIANG NORMAL UNIVERSITY, Urumqi (CN)

(72) Inventors: Kaitong LIU, Urumqi (CN); Yanhui ZHANG, Urumqi (CN); Xintong CAI, Urumqi (CN)

(21) Appl. No.: 19/384,475

(22) Filed: Nov. 10, 2025

(30) Foreign Application Priority Data
Nov. 21, 2024 (CN) 202411673469.1

(51) Int. Cl. C30B 7/14; C01B 35/12; C01G 21/00; G02F 1/355

(52) U.S. Cl. CPC C30B 7/14; C01B 35/127; C01G 21/00; G02F 1/3551

(57) ABSTRACT

A lead decahydroxydecaborate dihydroxy monoborate monohydrate nonlinear optical crystal, and its preparation method and application are provided. The chemical formula of this crystal is Pb₂B₁₀O₁₆(OH)₂·B(OH)₃·H₂O, its molecular weight is 892.35, and it belongs to the monoclinic crystal system, space group P2₁. The crystal is grown using a hydrothermal method in a closed system, or using a room temperature solution method in an open system.

### CROSS-REFERENCE TO RELATED APPLICATIONS

This application claims priority to Chinese Patent Application No. 202411673469.1, filed on November 21, 2024, the contents of which are hereby incorporated by reference.

### TECHNICAL FIELD

The present disclosure belongs to the technical field of inorganic chemistry, and particularly relates to a lead decahydroxydecaborate dihydroxy monoborate monohydrate nonlinear optical crystal, and a preparation method and an application thereof.

### BACKGROUND

Borates have consistently been a hot research direction in the field of nonlinear crystal materials due to their excellent properties and diverse structures. The boron (B) atom may form [BO₂] sticks, [BO₃] planar triangles, and [BO₄] tetrahedra with oxygen (O) atoms through sp, sp², and sp³ orbital hybridization. Borate nonlinear optical (NLO) crystals containing π-conjugated [BO₃] groups, due to their moderate NLO coefficients, moderate birefringence, wide transmission range, and high laser damage threshold, such as β-BaB₂O₄·(β-BBO), LiB₃O₅·(LBO), CsB₃O₅·(CBO), CsLiB₆O₁₀(CLBO), etc., have long been a focus of research. Introducing hydroxyl groups may modulate the three-dimensional structure of B-O groups in borates and construct two-dimensional layered structures. Many hydroxyborates with excellent properties have been reported, such as AEB₈O₁₅H₄ (AE = Ca, Sr), Ba₂[B₆O₉(OH)₄], Zn₂(BO₃)(OH), CsB₇O₁₀(OH)₂, Mg(H₂O)₆B₄O₅(OH)₄(H₂O)₃, Ca₂[B₅O₈(OH)]₂[B(OH)₃]·(OH)·4H₂O and Ba₂[B₆O₉(OH)₂][B₃O₃(OH)₄]·(OH)·4H₂O.

However, in recent years, when developing new nonlinear optical crystals, attention is paid not only to the optical and mechanical properties of the crystals but also increasingly to their preparation characteristics. There is a desire for new crystal materials to be easily prepared, allowing for the acquisition of large-size, high-quality nonlinear optical crystals at low cost. For this reason, the present disclosure proposes a novel lead decahydroxydecaborate dihydroxy monoborate monohydrate nonlinear optical crystal, and its preparation method and application.

### SUMMARY

To solve the aforementioned technical problems, the present disclosure proposes a novel lead decahydroxydecaborate dihydroxy monoborate monohydrate nonlinear optical crystal, and its preparation method and application.

To achieve the above objective, the present disclosure provides the following technical scheme.

The present disclosure proposes a lead decahydroxydecaborate dihydroxy monoborate monohydrate nonlinear optical crystal. The chemical formula of this crystal is Pb₂B₁₀O₁₆(OH)₂·B(OH)₃·H₂O, with a molecular weight of 892.35. It belongs to the monoclinic crystal system, space group P2₁. The unit cell parameters are a = 6.6484(2) Å, b = 20.8682(7) Å, c = 6.7336(2) Å, β = 119.0742(11)°, α = γ = 90°, and the unit cell volume is 816.50(4) Å³.

In the existing technology, there are methods and uses for preparing large-size calcium ammonium borate octahydrate nonlinear optical crystals (Patent Application No. CN201010606913.X), a compound sodium borate monohydrate nonlinear optical crystal, preparation method and use thereof (Patent Application No. CN201110339261.2), a compound calcium pentaborate monohydroxy monohydrate nonlinear optical crystal, preparation method and use thereof (Patent Application No. CN201410245947.9), and a barium tetrahydroxyborate nonlinear optical crystal, preparation method and use thereof (Patent Application No. CN201110365019.2). Compared to these aforementioned nonlinear optical crystals, the lead decahydroxydecaborate dihydroxy monoborate monohydrate nonlinear optical crystal of the present disclosure has an anionic framework consisting of a unique two-dimensional ²[B₅O₈(OH)]_{∞} layer. This layer is parallel to the ac plane, and two adjacent layers have opposite and back-to-back arrangements. Crystal water and [B(OH)₃] groups fill the space between two opposing ²[B₅O₈(OH)]_{∞} layers. Plumbum (Pb) atoms fill the 18-membered rings within the ²[B₅O₈(OH)]_{∞} layers. The different bonding forces in the structure of the layer constructed by boron-oxygen-hydrogen (BOH) groups result in completely different structure and growth habit.

The present disclosure also proposes a preparation method for the lead decahydroxydecaborate dihydroxy monoborate monohydrate nonlinear optical crystal. It is grown using a hydrothermal method in a closed system, or using a room temperature solution method in an open system.

The hydrothermal method involves mixing lead-containing compounds and boron-containing compounds, and preparing the crystal through a sealed hydrothermal reaction in a hydrothermal autoclave.

The room temperature solution method involves dissolving lead-containing compounds and boron-containing compounds in water to obtain a mixed solution, allowing it to stand at room temperature to obtain seed crystals, suspending the seed crystals inside the mixed solution using a thin platinum wire, and allowing it to stand at room temperature for growth.

In an embodiment, the lead-containing compound is one or more of PbF₂, PbO, PbCO₃, Pb(NO₃)₂, or PbSO₄. The boron-containing compound is H₃BO₃ or B₂O₃.

In an embodiment, the molar ratio of the lead-containing compound to the boron-containing compound is (2-4):11.

In an embodiment, in the hydrothermal method, the hydrothermal reaction involves heating at a rate of 10-60 degrees Celsius per hour to 150-220 degrees Celsius, maintaining the temperature for 24-120 hours, and then cooling to room temperature at a rate of 1-50 degrees Celsius per hour.

In an embodiment, in the room temperature solution method, the mixed solution is allowed to stand at room temperature for 5-20 days to obtain seed crystals.

In an embodiment, in the room temperature solution method, the seed crystals are suspended in the mixed solution and allowed to stand for growth at room temperature for 10-30 days.

More specifically, the lead decahydroxydecaborate dihydroxy monoborate monohydrate nonlinear optical crystal of the present disclosure is synthesized using the hydrothermal method, specifically including the following steps:

mixing a lead-containing compound (PbF₂, PbO, PbCO₃, Pb(NO₃)₂, or PbSO₄) and a boron-containing compound (H₃BO₃ or B₂O₃) uniformly according to a molar ratio of (2-4):11, loading the mixture into a hydrothermal autoclave, adding water, placing it in a constant temperature oven, heating to 150-220 degrees Celsius at a rate of 10-60 degrees Celsius per hour, maintaining the temperature for 24-120 hours, and then cooling to room temperature at a rate of 1-50 degrees Celsius per hour, thereby preparing the lead decahydroxydecaborate dihydroxy monoborate monohydrate nonlinear optical crystal.

More specifically, the lead decahydroxydecaborate dihydroxy monoborate monohydrate nonlinear optical crystal of the present disclosure is synthesized using the room temperature solution method, specifically including the following steps:

a, uniformly mixing a lead-containing compound (PbF₂, PbO, PbCO₃, Pb(NO₃)₂, or PbSO₄) and a boron-containing compound (H₃BO₃ or B₂O₃) according to a molar ratio of (2-4):11, placing the mixture into a cleaned glass container, adding 20-100 millilitres of deionized water,

then subjecting it to ultrasonic treatment for thorough mixing and dissolution, and filtering with filter paper to obtain a mixed solution;

b, placing the mixed solution obtained in step a into a clean glass container, sealing the container with weighing paper, placing it in a static environment without shaking, pollution, or air convection, puncturing several small holes in the seal to regulate the water evaporation rate in the solution, and letting it stand at room temperature for 5-20 days;

c, allowing crystal particles to grow at the bottom of the container from the solution in step b, until the size of the crystal particles no longer changes significantly, thus obtaining seed crystals; and

d, selecting seed crystals from step c that are transparent and free of cracks, suspending them inside the mixed solution prepared in step a using a thin platinum wire, and letting them stand for growth at room temperature for 10-30 days, thereby obtaining the lead decahydroxydecaborate dihydroxy monoborate monohydrate nonlinear optical crystal.

Compared to the existing technology, such as calcium decahydroxydecaborate dihydroxy monoborate monohydrate nonlinear optical crystal and preparation method thereof (CN201310504973.4), strontium decahydroxydecaborate dihydroxy monoborate monohydrate nonlinear optical crystal and preparation method thereof (CN201310504651.X), and barium decahydroxydecaborate dihydroxy monoborate monohydrate nonlinear optical crystal (CN201310504643.5), the lead decahydroxydecaborate dihydroxy monoborate monohydrate nonlinear optical crystal of the present disclosure may be stably grown in an open system (room temperature solution method) and may also be grown and prepared in a closed system (hydrothermal method). Furthermore, the hydrothermal preparation process does not require the addition of mineralizers (lithium hydroxide, sodium hydroxide, potassium hydroxide, ammonia water, or ethylenediamine). The advantage is that it does not introduce other impurity ions, facilitating the obtainment of higher quality single crystals. The preparation method of the present disclosure has the advantages of fast growth speed, low cost, and ease of obtaining large-size crystals.

The lead decahydroxydecaborate dihydroxy monoborate monohydrate nonlinear optical crystal of the present disclosure (Pb₂B₁₀O₁₆(OH)₂·B(OH)₃·H₂O) has different reaction equations for the synthesis process depending on the lead-containing and boron-containing compounds used, for example:

2PbF₂ + 11H₃BO₃ → Pb₂B₁₀O₁₆(OH)₂·B(OH)₃·H₂O + 4HF + 11H₂O; or

4PbO + 11B₂O₃ + 7H₂O → 2Pb₂B₁₀O₁₆(OH)₂·B(OH)₃·H₂O; or

2PbCO₃ + 11H₃BO₃ → Pb₂B₁₀O₁₆(OH)₂·B(OH)₃·H₂O + 2CO₂ + 2H₂O; or

4Pb(NO₃)₂ + 11B₂O₃ + 7H₂O → 2Pb₂B₁₀O₁₆(OH)₂·B(OH)₃·H₂O + 4NO₂; or

2PbSO₄ + 11H₃BO₃ → Pb₂B₁₀O₁₆(OH)₂·B(OH)₃·H₂O + 2SO₂ + 11H₂O.

The present disclosure also proposes the application of the lead decahydroxydecaborate dihydroxy monoborate monohydrate nonlinear optical crystal in the preparation of second harmonic generators, up or down frequency converters, and optical parametric oscillators.

In an embodiment, the lead decahydroxydecaborate dihydroxy monoborate monohydrate nonlinear optical crystal is used for generating second harmonic and fourth harmonic light output from the fundamental 1064 nanometers wave emitted by an Nd:AG laser.

In an embodiment, the lead decahydroxydecaborate dihydroxy monoborate monohydrate nonlinear optical crystal is used for generating deep ultraviolet second harmonic light with a wavelength below 200 nanometers.

Compared with the existing technology, the present disclosure has the following advantages and technical effects.

The lead decahydroxydecaborate dihydroxy monoborate monohydrate nonlinear optical crystal (Pb₂B₁₀O₁₆(OH)₂·B(OH)₃·H₂O) prepared by the method of the present disclosure has a centimeter-level size. By controlling the standing time or the hydrothermal reaction time, a correspondingly large-sized nonlinear optical crystal may be obtained. During the preparation process, the crystals grow easily, are large, transparent, and free of inclusions, and the method offers advantages such as fast growth speed, low cost, and ease of obtaining large-size crystals.

The lead decahydroxydecaborate dihydroxy monoborate monohydrate nonlinear optical crystal (Pb₂B₁₀O₁₆(OH)₂·B(OH)₃·H₂O) prepared in the present disclosure, based on its crystallographic data, allows the crystal blank to be oriented. The crystal may be cut to the required angle, thickness, and cross-sectional dimensions, and the light-passing surfaces of the crystal may be polished, enabling its use as a nonlinear optical device. It offers advantages such as a transmission range extending to the deep ultraviolet region (cut-off edge at 204 nanometers), stable physicochemical properties (thermogravimetric analysis shows stability up to 100 degrees Celsius), and ease of processing and storage.

### BRIEF DESCRIPTION OF THE DRAWINGS

The drawings forming a part of the present disclosure are used to provide a further understanding of the present disclosure. The schematic embodiments of the present disclosure and their descriptions are used to explain the present disclosure and do not constitute an undue limitation of the present disclosure. In the drawings:

FIG. 1 shows the powder X-ray diffraction pattern of the Pb₂B₁₀O₁₆(OH)₂·B(OH)₃·H₂O crystal prepared in Embodiment 1 of the present disclosure.

FIG. 2 shows a working principle diagram of a nonlinear optical device made using the Pb₂B₁₀O₁₆(OH)₂·B(OH)₃·H₂O crystal.

### DETAILED DESCRIPTION OF THE EMBODIMENTS

The various exemplary embodiments of the present disclosure are now described in detail. This detailed description should not be construed as a limitation of the present disclosure, but rather should be understood as a more detailed description of certain aspects, features, and embodiments of the present disclosure.

It should be understood that the terms used in the present disclosure are only for describing specific embodiments and are not intended to limit the present disclosure. In addition, for numerical ranges in the present disclosure, it should be understood that each intermediate value between the upper and lower limits of the range is also specifically disclosed. Every smaller range, defined by any stated value or intermediate value within a stated range and any other stated value or intermediate value within said range, is also included in the present disclosure. The upper and lower limits of these smaller ranges may be independently included or excluded from the range.

Unless otherwise stated, all technical and scientific terms used herein have the same meaning as commonly understood by one of ordinary skill in the art to which this disclosure belongs. Although only optional methods and materials are described herein, any methods and materials similar or equivalent to those described may also be used in the practice or testing of the present disclosure. All documents mentioned in this specification are incorporated by reference to disclose and describe the methods and/or materials related to the documents. In the event of conflict with any incorporated document, the content of this specification shall prevail.

Various modifications and changes may be made to the specific embodiments described in the specification of the present disclosure without departing from the scope or spirit of the disclosure, which will be obvious to those skilled in the art. Other embodiments obtained from the description of the present disclosure will be obvious to those skilled in the art. The specification and embodiments of the present disclosure are to be considered exemplary only.

Regarding the terms used herein, such as "comprise", "include", "have", "contain", etc., they are all open-ended terms, meaning inclusion but not limited to.

The embodiments of the present disclosure propose a lead decahydroxydecaborate dihydroxy monoborate monohydrate nonlinear optical crystal. The chemical formula of this crystal is Pb₂B₁₀O₁₆(OH)₂·B(OH)₃·H₂O, its molecular weight is 892.35, it belongs to the monoclinic crystal system, space group P2₁, and its unit cell parameters are a = 6.6484(2) Å, b = 20.8682(7) Å, c = 6.7336(2) Å, β = 119.0742(11)°, α = γ = 90°, and the unit cell volume is 816.50(4) Å³.

The Pb₂B₁₀O₁₆(OH)₂·B(OH)₃·H₂O crystal prepared in the embodiment of the present disclosure has an anionic framework composed of a unique two-dimensional ²[B₅O₈(OH)]_{∞} layer. This layer is parallel to the ac plane, and two adjacent layers have opposite and back-to-back arrangements. Crystal water and [B(OH)₃] groups fill the space between two opposing ²[B₅O₈(OH)]_{∞} layers. Plumbum (Pb) atoms fill the 18-membered rings within the ²[B₅O₈(OH)]_{∞} layers. The different bonding forces in the structure of the layer constructed by the boron-oxygen-hydrogen (BOH) groups result in completely different structure and growth habit.

In the embodiments of the present disclosure, the obtained Pb₂B₁₀O₁₆(OH)₂·B(OH)₃·H₂O crystals have dimensions of (1.0-1.7) centimeters × (0.8-1.5) centimeters × (0.5-1.0) centimeters, for example: 1.5 centimeters × 1.5 centimeters × 1.0 centimeter, 1.5 centimeters × 1.3 centimeters × 0.8 centimeters, 1.3 centimeters × 1.0 centimeter × 1.0 centimeter, 1.7 centimeters × 1.4 centimeters × 0.8 centimeters, 1.0 centimeter × 0.8 centimeters × 0.5 centimeters, and 1.0 centimeter × 0.8 centimeters × 0.5 centimeters.

The embodiments of the present disclosure also propose a preparation method for the lead decahydroxydecaborate dihydroxy monoborate monohydrate nonlinear optical crystal. The crystal is grown using a hydrothermal method in a closed system, or using a room temperature solution method in an open system.

The hydrothermal method involves mixing lead-containing compounds and boron-containing compounds, and preparing the crystal through a sealed hydrothermal reaction in a hydrothermal autoclave.

The room temperature solution method involves dissolving lead-containing compounds and boron-containing compounds in water to obtain a mixed solution, allowing the solution to stand at room temperature to obtain seed crystals, suspending the seed crystals inside the mixed solution using a thin platinum wire, and allowing them to stand at room temperature for growth.

In an optional embodiment of the present disclosure, the lead-containing compound is one or more selected from PbF₂, PbO, PbCO₃, Pb(NO₃)₂, or PbSO₄. The boron-containing compound is H₃BO₃ or B₂O₃.

In an optional embodiment of the present disclosure, the molar ratio of the lead-containing compound to the boron-containing compound is (2-4):11.

In an optional embodiment of the present disclosure, the hydrothermal reaction in the hydrothermal method involves heating at a rate of 10-60 degrees Celsius per hour to a temperature of 150-220 degrees Celsius, maintaining the temperature for 24-120 hours, and then cooling to room temperature at a rate of 1-50 degrees Celsius per hour.

In an optional embodiment of the present disclosure, in the room temperature solution method, the mixed solution is allowed to stand at room temperature for 5-20 days to obtain seed crystals.

In an optional embodiment of the present disclosure, in the room temperature solution method, the seed crystals are suspended in the mixed solution and allowed to stand for growth at room temperature for 10-30 days.

In an optional embodiment of the present disclosure, in the room temperature solution method, transparent and crack-free seed crystals are suspended inside the mixed solution using a thin platinum wire.

For the lead decahydroxydecaborate dihydroxy monoborate monohydrate nonlinear optical crystal (Pb₂B₁₀O₁₆(OH)₂·B(OH)₃·H₂O) of the present disclosure, the reaction equation for the synthesis process differs depending on the lead-containing and boron-containing compounds used, for example:

2PbF₂ + 11H₃BO₃ → Pb₂B₁₀O₁₆(OH)₂·B(OH)₃·H₂O + 4HF + 11H₂O; or

4PbO + 11B₂O₃ + 7H₂O → 2Pb₂B₁₀O₁₆(OH)₂·B(OH)₃·H₂O; or

2PbCO₃ + 11H₃BO₃ → Pb₂B₁₀O₁₆(OH)₂·B(OH)₃·H₂O + 2CO₂ + 2H₂O; or

4Pb(NO₃)₂ + 11B₂O₃ + 7H₂O → 2Pb₂B₁₀O₁₆(OH)₂·B(OH)₃·H₂O + 4NO₂; or

2PbSO₄ + 11H₃BO₃ → Pb₂B₁₀O₁₆(OH)₂·B(OH)₃·H₂O + 2SO₂ + 11H₂O.

In the embodiments of the present disclosure, the term "room temperature" refers to "25 ± 2 degrees Celsius".

The technical scheme of the present disclosure is further described below through embodiments.

### Embodiment 1

Preparation of Pb₂B₁₀O₁₆(OH)₂·B(OH)₃·H₂O crystal by hydrothermal method.

A lead-containing compound (PbF₂) and a boron-containing compound (H₃BO₃) are uniformly mixed according to a molar ratio of 2:11. The mixture is loaded into a hydrothermal autoclave, and water is added according to a mass ratio of raw materials to water of 1:5. The autoclave is placed in a constant temperature oven, heated to 220 degrees Celsius at a rate of 50 degrees Celsius per hour, maintained at that temperature for 120 hours, and then cooled to room temperature at a rate of 10 degrees Celsius per hour. A Pb₂B₁₀O₁₆(OH)₂·B(OH)₃·H₂O crystal with dimensions of 1.5 centimeters × 1.5 centimeters × 1.0 centimeter is thereby prepared. The reaction equation for the synthesis process is: 2PbF₂ + 11H₃BO₃ → Pb₂B₁₀O₁₆(OH)₂·B(OH)₃·H₂O + 4HF + 11H₂O.

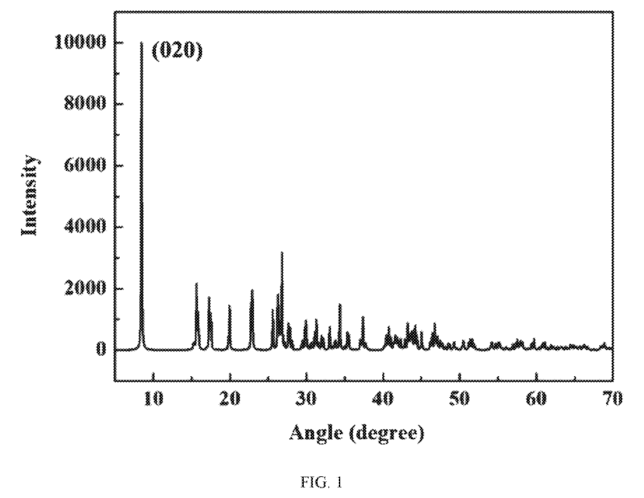

The powder X-ray diffraction pattern of the Pb₂B₁₀O₁₆(OH)₂·B(OH)₃·H₂O crystal prepared in Embodiment 1 of the present disclosure is shown in FIG. 1. Based on FIG. 1, it may be stated that Pb₂B₁₀O₁₆(OH)₂·B(OH)₃·H₂O possesses a layered borate anion group structure. This layered structure is formed by basic building blocks [B₅O₁₀(OH)] groups connected through shared vertex oxygen atoms, constituting a ²[B₅O₈(OH)]_{∞} layer parallel to the ac plane. This is consistent with the preferred orientation along the (020) direction observed in FIG. 1.

### Embodiment 2

Preparation of Pb₂B₁₀O₁₆(OH)₂·B(OH)₃·H₂O crystal by hydrothermal method.

A lead-containing compound (PbO) and a boron-containing compound (B₂O₃) are uniformly mixed according to a molar ratio of 4:11. The mixture is loaded into a hydrothermal autoclave, and water is added. The autoclave is placed in a constant temperature oven, heated to 220 degrees Celsius at a rate of 40 degrees Celsius per hour, maintained at that temperature for 100 hours, and then cooled to room temperature at a rate of 15 degrees Celsius per hour. A Pb₂B₁₀O₁₆(OH)₂·B(OH)₃·H₂O crystal with dimensions of 1.5 centimeters × 1.3 centimeters × 0.8 centimeters is thereby prepared. The reaction equation for the synthesis process is: 4PbO + 11B₂O₃ + 7H₂O → 2Pb₂B₁₀O₁₆(OH)₂·B(OH)₃·H₂O.

### Embodiment 3

Preparation of Pb₂B₁₀O₁₆(OH)₂·B(OH)₃·H₂O crystal by hydrothermal method.

A lead-containing compound (PbCO₃) and a boron-containing compound (H₃BO₃) are uniformly mixed according to a molar ratio of 2:11. The mixture is loaded into a hydrothermal autoclave, and water is added. The autoclave is placed in a constant temperature oven, heated to 210 degrees Celsius at a rate of 40 degrees Celsius per hour, maintained at that temperature for 80 hours, and then cooled to room temperature at a rate of 13 degrees Celsius per hour. A Pb₂B₁₀O₁₆(OH)₂·B(OH)₃·H₂O crystal with dimensions of 1.3 centimeters × 1.0 centimeter × 1.0 centimeter is thereby prepared. The reaction equation for the synthesis process is: 2PbCO₃ + 11H₃BO₃ → Pb₂B₁₀O₁₆(OH)₂·B(OH)₃·H₂O + 2CO₂ + 2H₂O.

### Embodiment 4

Preparation of Pb₂B₁₀O₁₆(OH)₂·B(OH)₃·H₂O crystal by hydrothermal method.

A lead-containing compound (Pb(NO₃)₂) and a boron-containing compound (B₂O₃) are uniformly mixed according to a molar ratio of 4:11. The mixture is loaded into a hydrothermal autoclave, and water is added. The autoclave is placed in a constant temperature oven, heated to 220 degrees Celsius at a rate of 10 degrees Celsius per hour, maintained at that temperature for 120 hours, and then cooled to room temperature at a rate of 1 degree Celsius per hour. A Pb₂B₁₀O₁₆(OH)₂·B(OH)₃·H₂O crystal with dimensions of 1.7 centimeters × 1.4 centimeters × 0.8 centimeters is thereby prepared. The reaction equation for the synthesis process is: 4Pb(NO₃)₂ + 11B₂O₃ + 7H₂O → 2Pb₂B₁₀O₁₆(OH)₂·B(OH)₃·H₂O + 4NO₂.

### Embodiment 5

Preparation of Pb₂B₁₀O₁₆(OH)₂·B(OH)₃·H₂O crystal by hydrothermal method.

A lead-containing compound (PbSO₄) and a boron-containing compound (H₃BO₃) are uniformly mixed according to a molar ratio of 2:11. The mixture is loaded into a hydrothermal autoclave, and water is added. The autoclave is placed in a constant temperature oven, heated to 190 degrees Celsius at a rate of 60 degrees Celsius per hour, maintained at that temperature for 120 hours, and then cooled to room temperature at a rate of 20 degrees Celsius per hour. A Pb₂B₁₀O₁₆(OH)₂·B(OH)₃·H₂O crystal with dimensions of 1.0 centimeter × 0.8 centimeters × 0.5 centimeters is thereby prepared. The reaction equation for the synthesis process is: 2PbSO₄ + 11H₃BO₃ → Pb₂B₁₀O₁₆(OH)₂·B(OH)₃·H₂O + 2SO₂ + 11H₂O.

### Embodiment 6

Preparation of Pb₂B₁₀O₁₆(OH)₂·B(OH)₃·H₂O crystal by room temperature solution method.

(a) A lead-containing compound (Pb(NO₃)₂) and a boron-containing compound (H₃BO₃) are uniformly mixed according to a molar ratio of 2:11. The mixture is placed into a cleaned glass container, 100 milliliters of deionized water is added, and then the mixture is subjected to ultrasonic treatment for thorough mixing and dissolution. It is filtered with filter paper to obtain a mixed solution.

(b) The mixed solution obtained in step (a) is placed into a clean glass container. The container is sealed with weighing paper and placed in a static environment without shaking, pollution, or air convection. Approximately 20 small holes are punctured in the seal to regulate the water evaporation rate in the solution to 0.05 milliliters per day. The container is allowed to stand at room temperature for 10 days.

(c) Crystal particles are allowed to grow at the bottom of the container from the solution in step (b), until the size of the crystal particles no longer changes significantly, thereby obtaining seed crystals.

(d) Seed crystals from step (c) that are transparent and free of cracks are selected. They are suspended inside the mixed solution prepared in step (a) using a thin platinum wire and allowed to stand for growth at room temperature for 20 days. A Pb₂B₁₀O₁₆(OH)₂·B(OH)₃·H₂O crystal with dimensions of 1.0 centimeter × 0.8 centimeters × 0.5 centimeters is thereby prepared. The reaction equation for the synthesis process is: 2PbSO₄ + 11H₃BO₃ → Pb₂B₁₀O₁₆(OH)₂·B(OH)₃·H₂O + 2SO₂ + 11H₂O.

### Embodiment 7

The procedure is the same as in Embodiment 1, with the only difference being that the temperature is increased to 150 degrees Celsius at a rate of 60 degrees Celsius per hour, maintained for 120 hours, and then decreased to room temperature at a rate of 50 degrees Celsius per hour. A Pb₂B₁₀O₁₆(OH)₂·B(OH)₃·H₂O crystal with dimensions of 0.5 centimeters × 0.3 centimeters × 0.1 centimeters is thereby prepared.

### Embodiment 8

The procedure is the same as in Embodiment 1, with the only difference being that the temperature is increased to 220 degrees Celsius at a rate of 10 degrees Celsius per hour, maintained for 24 hours, and then decreased to room temperature at a rate of 1 degree Celsius per hour. A Pb₂B₁₀O₁₆(OH)₂·B(OH)₃·H₂O crystal with dimensions of 1.0 centimeter × 0.8 centimeters × 0.5 centimeters is thereby prepared.

### Embodiment 9

The procedure is the same as in Embodiment 6, with the only difference being that in step (b), the mixture is allowed to stand at room temperature for 5 days. A Pb₂B₁₀O₁₆(OH)₂·B(OH)₃·H₂O crystal with dimensions of 0.3 centimeters × 0.2 centimeters × 0.05 centimeters is thereby prepared.

### Embodiment 10

The procedure is the same as in Embodiment 6, with the only difference being that in step (b), the mixture is allowed to stand at room temperature for 20 days. A Pb₂B₁₀O₁₆(OH)₂·B(OH)₃·H₂O crystal with dimensions of 1.0 centimeter × 0.7 centimeters × 0.4 centimeters is thereby prepared.

### Embodiment 11

The procedure is the same as in Embodiment 6, with the only difference being that in step (d), the seed crystals are allowed to stand for growth at room temperature for 10 days. A Pb₂B₁₀O₁₆(OH)₂·B(OH)₃·H₂O crystal with dimensions of 0.6 centimeters × 0.4 centimeters × 0.2 centimeters is thereby prepared.

### Embodiment 12

The procedure is the same as in Embodiment 6, with the only difference being that in step (d), the seed crystals are allowed to stand for growth at room temperature for 30 days. A Pb₂B₁₀O₁₆(OH)₂·B(OH)₃·H₂O crystal with dimensions of 1.2 centimeters × 0.9 centimeters × 0.5 centimeters is thereby prepared.

### Application Embodiment 1

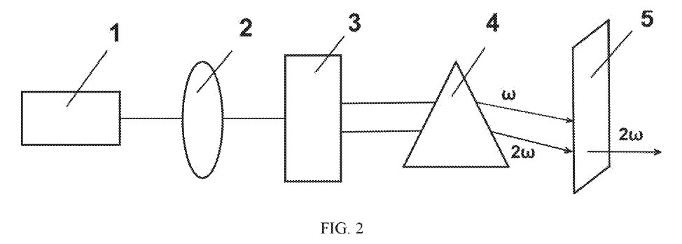

The working principle diagram of a nonlinear optical device made using the Pb₂B₁₀O₁₆(OH)₂·B(OH)₃·H₂O crystal is shown in FIG. 2, where 1 is a laser, 2 is an infrared beam, 3 is the Pb₂B₁₀O₁₆(OH)₂·B(OH)₃·H₂O crystal, 4 is an emitted beam, and 5 is a filter.

The Pb₂B₁₀O₁₆(OH)₂·B(OH)₃·H₂O crystal prepared in Embodiment 1 is processed along the phase-matching direction and is installed at the position marked as number 3 according to FIG. 2. At room temperature, a Q-switched Nd:YAG laser is used as the light source. The infrared beam 2 with a wavelength of 1064 nanometers emitted from the Q-switched Nd:YAG laser 1 is directed into the Pb₂B₁₀O₁₆(OH)₂·B(OH)₃·H₂O crystal 3 prepared in Embodiment 1. The other Embodiments 2-12 are assembled and tested according to the above method.

The results show that the Pb₂B₁₀O₁₆(OH)₂·B(OH)₃·H₂O crystals from Embodiments 1-12 may all generate green frequency doubling light (emitted beam 4) with a wavelength of 532 nanometers. The output intensity is about 2.1 times that of potassium dihydrogen phosphate crystal (KDP) under the same conditions. This is because the Pb₂B₁₀O₁₆(OH)₂·B(OH)₃·H₂O crystals from Embodiments 1-12, which crystallize in the P2₁ space group, possess the same structure and therefore exhibit the same optical properties.

The foregoing descriptions are merely optional specific embodiments of the present disclosure. However, the protection scope of the present disclosure is not limited thereto. Any change or substitution that may be easily conceived by a person skilled in the art within the technical scope disclosed in the present disclosure shall fall within the protection scope of the present disclosure. Therefore, the protection scope of the present disclosure shall be subject to the protection scope defined by the claims.

What is claimed is:

1. A lead decahydroxydecaborate dihydroxy monoborate monohydrate nonlinear optical crystal, wherein a chemical formula of the crystal is Pb₂B₁₀O₁₆(OH)₂·B(OH)₃·H₂O, a molecular weight is 892.35, the crystal belongs to a monoclinic crystal system with space group P2₁ unit cell parameters are a = 6 .6484(2) Å, b = 20 .8682(7) Å, c = 6.7336(2) Å, β = 119.0742(11)°, α = γ = 90°, and a unit cell volume is 816.50(4) Å³.

2. A preparation method for the lead decahydroxydecaborate dihydroxy monoborate monohydrate nonlinear optical crystal according to claim 1, wherein the crystal is grown using a hydrothermal method in a closed system, or using a room temperature solution method in an open system;
the hydrothermal method comprises mixing a lead-containing compound and a boron-containing compound, and preparing the crystal through a sealed hydrothermal reaction in a hydrothermal autoclave; and
the room temperature solution method comprises dissolving the lead-containing compound and the boron-containing compound in water to obtain a mixed solution, allowing the mixed solution to stand at room temperature to obtain seed crystals, and suspending the seed crystals inside the mixed solution for growth at the room temperature.

3. The preparation method for the lead decahydroxydecaborate dihydroxy monoborate monohydrate nonlinear optical crystal according to claim 2, wherein the lead-containing compound is one or more selected from PbF_{2,} PbO, PbCO₃ Pb(NO₃)₂ or PbSO₄; and the boron-containing compound is H₃BO₃ or B₂O₃.

4. The preparation method for the lead decahydroxydecaborate dihydroxy monoborate monohydrate nonlinear optical crystal according to claim 2, wherein a molar ratio of the lead-containing compound to the boron-containing compound is (2-4.) : 11.

5. The preparation method for the lead decahydroxydecaborate dihydroxy monoborate monohydrate nonlinear optical crystal according to claim 2, wherein the sealed hydrothermal reaction in the hydrothermal method comprises heating to 150-220 degrees Celsius at a rate of 10-60 degrees Celsius per hour, maintaining a temperature for 24-120 hours, and then cooling to the room temperature at a rate of 1-50 degrees Celsius per hour.

6. The preparation method for the lead decahydroxydecaborate dihydroxy monoborate monohydrate nonlinear optical crystal according to claim 2, wherein in the room temperature solution method, the mixed solution is allowed to stand at the room temperature for 5-20 days to obtain the seed crystals.

7. The preparation method for the lead decahydroxydecaborate dihydroxy monoborate monohydrate nonlinear optical crystal according to claim 2, wherein in the room temperature solution method, the seed crystals are suspended in the mixed solution and allowed to stand for growth at the room temperature for 10-30 days.
